(19) United States
(12) Patent Application Publication
(10) Pub. No.: US 2016/0093921 A1
(43) Pub. Date: Mar. 31, 2016

(54) CELL VOLTAGE SENSING FOR RECHARGEABLE BATTERY PACKS

(71) Applicant: Apple Inc., Cupertino, CA (US)

(72) Inventors: Karthik Kadirvel, San Jose, CA (US); Soundararajan Manthiri, Cupertino, CA (US); Salvatore Reddiconto, San Jose, CA (US); Liquan Tan, Cupertino, CA (US)

(21) Appl. No.: 14/804,121

(22) Filed: Jul. 20, 2015

Related U.S. Application Data
(60) Provisional application No. 62/055,613, filed on Sep. 25, 2014.

(51) Int. Cl. H01M 10/42; H01M 2/34; H01M 10/48; H01M 2/30; H02J 7/00; G01R 31/36

(52) U.S. Cl. CPC H01M 10/425; H02J 7/0021; H02J 7/0026; H02J 7/0052; G01R 31/3658; H01M 10/48; H01M 2/30; H01M 2/34; H02J 2007/0059; H01M 2200/00; H01M 2010/4271

(57) ABSTRACT

A battery system has positive and negative pack terminals, and positive and negative sense terminals. An electrochemical cell assembly has positive and negative cell terminals. An electrically conductive power path has a positive leg that connects the positive cell terminal to the positive pack terminal, and a negative leg that connects the negative cell terminal to the negative pack terminal. A power switch circuit is connected in the power path. An electrically conductive sense path separate from the power path has a positive leg that connects the positive cell terminal to the positive sense terminal, and a negative leg that connects to the negative sense terminal. A sense switch circuit is connected in the sense path. Other embodiments are also described and claimed.

This non-provisional application claims the benefit of the earlier filing date of U.S. Provisional Application No. 62/055,613, filed Sep. 25, 2014.

An embodiment of the invention is related to rechargeable battery packs and circuitry for monitoring battery voltage and for charging the battery. Other embodiments are also described.

### BACKGROUND

Rechargeable battery systems such as those that use lithium-based electrochemical cells are typically charged at up to a “1C” charge rate, which is a charging current that results in the battery becoming fully charged in about one hour. Automatic chargers monitor the pack voltage (the total voltage of the battery) so as to not exceed a predetermined threshold, while regulating the charge current until the pack voltage reaches a predetermined fully charged level. In the case of multi-cell battery packs, connections are provided to the individual cells of the pack, so as to allow a balancing circuit to bleed off charge from one cell that is charging too quickly relative to the other cells, so as to maintain the cell voltages approximately at the same level and therefore prevent overcharging of a particular cell in order to place all cells in the same charge state. The charging algorithm relies upon an external pack voltage to reduce the charging current when the pack voltage is approaching its predetermined full state of charge (as indicated by the pack voltage reaching a predetermined threshold).

### SUMMARY

When charging current is increased substantially above 1C, and particularly in situations where the battery pack has greater capacity such that the charging current is also greater, there is an appreciable IR voltage drop across the parasitic resistance of the electrically conductive power path that connects each cell through the battery pack out to an off-pack battery voltage monitoring and charging circuit. The parasitic resistance includes variations in circuit board and/or flex circuit resistance, power transistor switch on-resistance, and internal cell resistance. If the charging algorithm relies upon a pack voltage measurement taken at the exposed pack (power) terminals at a pack connector, then the charging current will be reduced too soon, thereby leaving the battery pack not fully charged.

An embodiment of the invention is a battery system in which there is an electrically conductive sense path that is separate from a power path and that connects the positive and negative cell terminals of an electrochemical cell assembly to positive and negative sense terminals, respectively. Thus, in addition to the positive and negative pack terminals (also referred to here as the power terminals), the battery system has positive and negative sense terminals that are connected to the cell assembly through a separate conductive sense path, thus providing a pair of dedicated sense lines to measure the cell voltage as an analog signal. The sense terminals may be connected to a voltage sensing circuit, which may be outside the pack or it may be packaged within the pack housing. A battery charging circuit can rely upon the voltage sensing circuit to more accurately determine when the pack has reached a full charge state. This allows the battery pack to more closely reach its true state of full charge.

In addition to a power switch circuit that is connected in the power path (for purposes of cutting off current in the power path to protect the cell in the event of a fault condition, such as an over voltage or overcharge condition, an under voltage or undercharge condition, or an overcurrent condition), the battery system further includes a sense switch circuit that is connected in the sense path. A protection control circuit may be provided that asserts a control signal that is applied to the sense switch circuit to cut off current in the sense path, in response to detecting a fault condition. In one embodiment, both the power switch circuit that is in the power path and the sense switch circuit that is in the sense path may be connected to the same control signal, which may be produced by the same protection control circuit.

While the sense switch circuit electrically isolates the cell assembly along the sense path when there is a fault condition, another embodiment of the invention provides for protection against excessive current in the sense path, by the addition of one or more discrete, series-connected resistors in the sense path. The resistor should be selected to have a resistance value in view of the impedance of the sense path, so as to limit a short circuit current though the sense path to thereby avoid damage, including overheating of the sense path during a short circuit fault.

In accordance with another embodiment of the invention, accurate monitoring of a battery pack's voltage may be achieved by the addition of a voltage sensing circuit whose first and second input nodes are connected to the positive and negative cell terminals, respectively, while its first and second output nodes are connected to positive and negative sense terminals, respectively, that may be individually accessible from outside of the pack. The cell voltage sensing circuit may be contained within the battery pack housing. A separate power path connects the cell terminals to positive and negative pack terminals, and a switch circuit in the power path serves to protect the cell assembly during a fault condition that, in one embodiment, may be detected by a protection control circuit. To prevent a leakage path that may slowly run down the charge of the pack, the voltage sensing circuit may be implemented using a voltage divider and amplifier circuit that is activated only during charging, in accordance with a control signal that may be asserted by the protection control circuit or, alternatively, by an external control circuit (from outside of the pack). In such an embodiment, the positive and negative sense terminals, rather than provide a raw cell voltage, provide an amplified or conditioned, analog version of the cell voltage.

The above summary does not include an exhaustive list of all aspects of the present invention. It is contemplated that the invention includes all systems and methods that can be practiced from all suitable combinations of the various aspects summarized above, as well as those disclosed in the Detailed Description below and particularly pointed out in the claims filed with the application. Such combinations have particular advantages not specifically recited in the above summary.

### BRIEF DESCRIPTION OF THE DRAWINGS

The embodiments of the invention are illustrated by way of example and not by way of limitation in the figures of the accompanying drawings in wHch like references indicate similar elements. It should be noted that references to “an” or “one” embodiment of the invention in this disclosure are not necessarily to the same embodiment, and they mean at least one. Also, for the sake of conciseness, a given figure may be used to illustrate the features of more than one embodiment of the invention, and not all elements in the figure may be required for a given embodiment.

FIG. 1 is a combined block diagram and circuit schematic of part of a battery system, in accordance with an embodiment of the invention.

FIG. 2 is a combined block diagram and circuit schematic of the battery system of FIG. 1 including a voltage sensing circuit and a charging circuit.

FIG. 3 illustrates another embodiment of the battery system.

FIG. 4 shows a battery system in which a voltage sensing circuit provides an amplified or otherwise conditioned, analog measure of cell voltage at the sensed terminals.

### DETAILED DESCRIPTION

Several embodiments of the invention with reference to the appended drawings are now explained. Whenever the shapes, relative positions and other aspects of the parts described in the embodiments are not explicitly defined, the scope of the invention is not limited only to the parts shown, which are meant merely for the purpose of illustration. Also, while numerous details are set forth, it is understood that some embodiments of the invention may be practiced without these details. In other instances, well-known circuits, structures, and techniques have not been shown in detail so as not to obscure the understanding of this description.

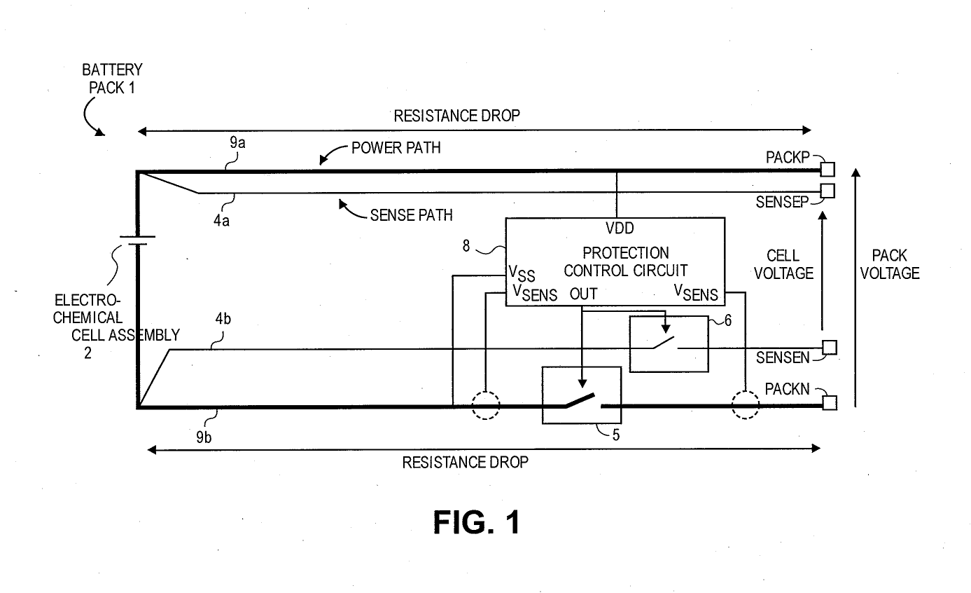

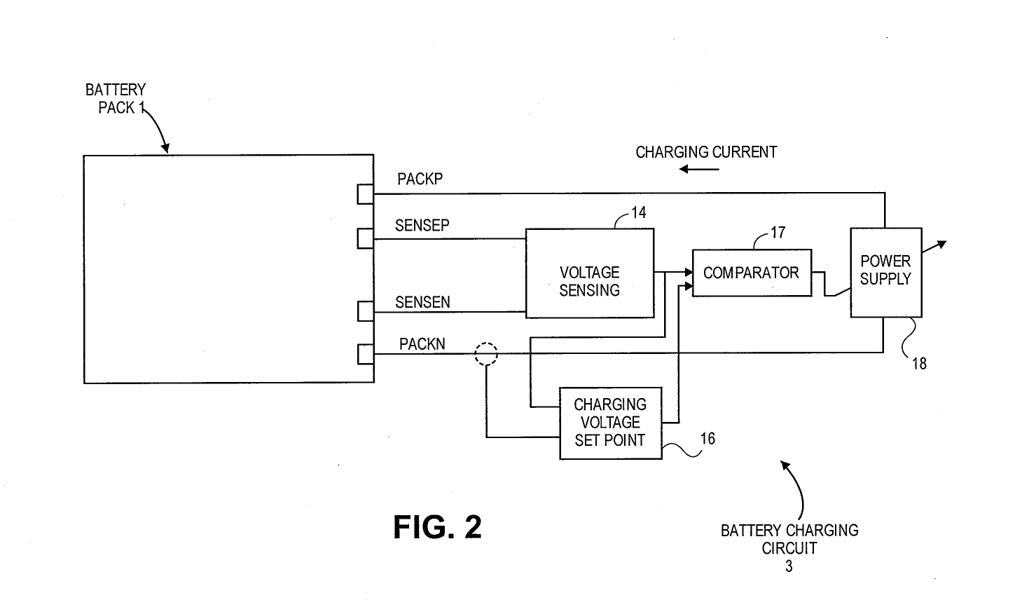

FIG. 1 is a combined block diagram and circuit schematic of part of a battery system, in accordance with an embodiment of the invention. In this embodiment, dedicated sense lines and sense terminals are provided to measure cell voltage of an electromechanical cell 2 (which may be part of a battery pack 1) for use by a charging circuit 3 (not shown in FIG. 1, but see FIG. 2). This may facilitate charging at high currents (e.g., greater than 1C) by providing more precise control of the actual cell voltage at which charging is cutoff. Such accurate cell voltage sensing may allow high current charging and increased energy storage in the cell at the conclusion of the charging cycle. This technique allows the charging parameters used during the charging cycles (e.g., the charging battery voltage, that is compared to a previously-set threshold voltage of a charging profile or algorithm) to maintain accuracy, despite the inherent voltage drop that is caused by the resistance along the power path as seen in FIG. 1. This accuracy may be maintained even while cell resistance changes, for example, due to cell aging. In addition, as described below, cell safety concerns are also addressed through the addition of a sense switch circuit in the sense path.

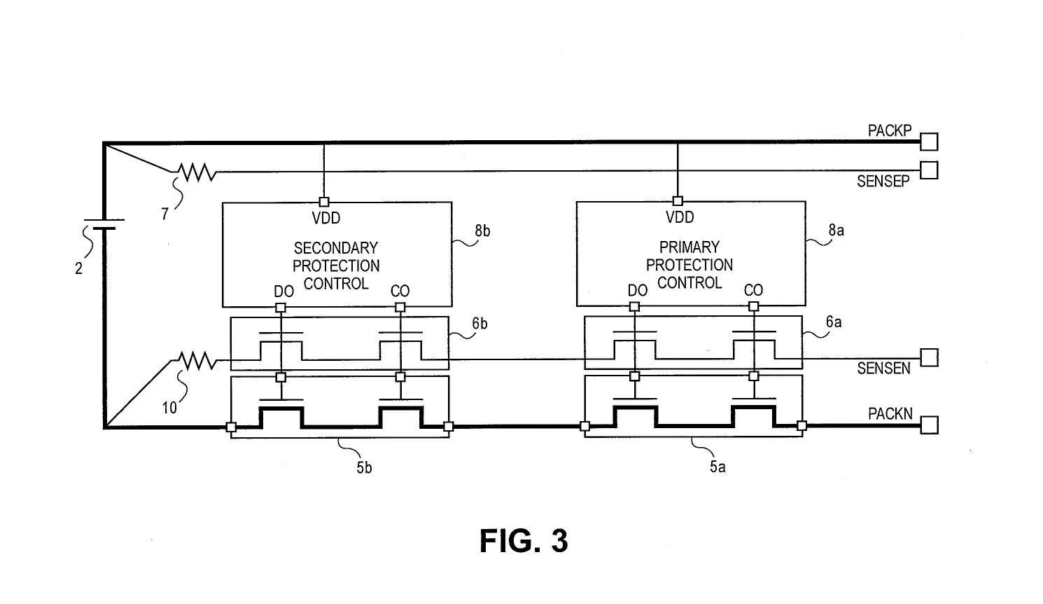

As seen in FIG. 1, an embodiment of the invention may be a battery system in which an electrochemical cell 2 assembly has a positive cell terminal and a negative cell terminal that are connected to positive and negative pack terminals, PACKP and PACKN, respectively, through respective positive and negative legs as shown. In the embodiment of FIG. 1, the positive leg 9a has no active devices in its path, while the negative leg 9b has a power switch circuit 5 that is connected in series between the cell assembly 2 and PACKN. The power switch circuit 5 may alternatively be connected in the positive leg 9a of the power path, between the cell 2 and PACKP. There may be more than one switch circuit in the same leg. Additionally or alternatively, there may be a switch circuit in both legs 9a, 9b, or there may be an active device in one of the legs and a passive device (e.g., a current sense resistor) in the other leg or there may be different types of active device in the two legs, as appropriate for the given situation. An active device may be any three-terminal device such as a transistor that has a control input for controlling current through the device, whereas a passive device is a two terminal device such as a diode, resistor, a capacitor, an inductor, or a fuse. The switch circuit 5 serves to cutoff current to the terminals of cell assembly 2 through the power path, for example, during a fault condition. In many instances, and in particular with lithium-based rechargeable electrochemical cells, it is important to quickly cutoff current to the cell assembly 2 upon encountering a fault condition. While in FIG. 1, the switch circuit 5 is depicted generically as a switch that receives a control signal from a protection control circuit 8, various designs for the switch circuit 5 are possible, including the use of metal oxide insulated gate field effect transistors, and other types of devices such as a resettable thermally sensitive overcurrent protection device that automatically transitions into an open circuit state (in response to excessive current through the power path resulting in heating of a heating element beyond a set threshold). Another approach is depicted in FIG. 3 in which a series of two insulated gate field effect transistors are provided for proper protection during both charge and discharge.

The protection control circuit 8 may be powered by the cell assembly 2, through its Vdd and Vss nodes as shown. The protection control circuit 8 signals the power switch circuit 5 into an open circuit state in response to detecting a fault condition. The fault condition may be an overvoltage state (or overcharging of cell assembly 2), an undervoltage state or undercharge state, or an overcurrent state during charging or during discharge. The protection control circuit 8 need not be able to detect all such fault conditions and may be configured to detect any combination of the three fault conditions.

The overcurrent fault may be detected through a voltage sense node Vsens that may be coupled to a sense resistor (not shown) that is in the power path. It should be noted that other techniques for detecting an overcurrent condition are possible including, for example, the use of a current mirror circuit or a Hall effect sensor.

Still referring to FIG. 1, addition to the positive and negative pack terminals, positive and negative sense terminals SENSEP and SENSEN, respectively, are provided which are connected by an electrically conductive sense path (separate from the power path) e.g., sense positive leg 4a and sense positive leg 4b to the terminals of the cell assembly 2. In one embodiment, the point at which a sense path and a power path are joined to the same terminal of the cell assembly 2 (as depicted in FIG. 1) is an anode or cathode current collector of the cell assembly 2. In one embodiment, the sense path has a smaller conducting area or conduction cross-section than its counterpart power path, and this characteristic holds along the entirety of the paths starting from where they are joined to the anode or cathode current collector and ending at the PACKP and SENSEP (or PACKN and SENSEN) terminals, respectively.

The sense path passes through a sense switch circuit 6, which may be said to be connected in series or in the sense path as shown (such that all current in the path passes through the sense switch circuit 6). The sense switch circuit 6 cuts off current in the sense path, in response to a control signal, which in some instances may be the same control signal that is produced by the protection control circuit 8 for signaling the power switch circuit 5. In this manner, faults detected by the protection control circuit 8 in the power path may result in a shutoff of current in the sense path. For example, while a voltage sensing circuit (see FIG. 2) is connected to the sense terminals, a fault condition that is rooted in the sense terminals or the sense path may be detected by the protection control circuit 8 as an overvoltage or undervoltage on the power path, and may be responded to by the protection control circuit 8 signaling the sense switch circuit 6 so that the electrochemical cell assembly 2 is protected from such a fault condition. Examples include an accidental short circuit, or a slow leak between the sense terminals that over time causes the voltage of the electrochemical cell assembly 2 to drop to a prohibitively low level. The protection control circuit 8 may detect these conditions as part its normal monitoring of cell voltage through its connections to the power path as shown. Accordingly, the addition of the sense path and the sense switch circuit 6 may be a relatively inexpensive modification where the existing capabilities of the protection control circuit 8 can be leveraged to prevent the failure of the electrochemical cell assembly 2 due to a fault that is rooted in the sense path.

For greater reliability or fault tolerance, a separate current sensing circuit (not shown) may be added that is used by the protection control circuit 8 to detect an overcurrent condition in the sense path; the protection control circuit in that case would, in response, signal the sense switch circuit 6 into its open circuit state.

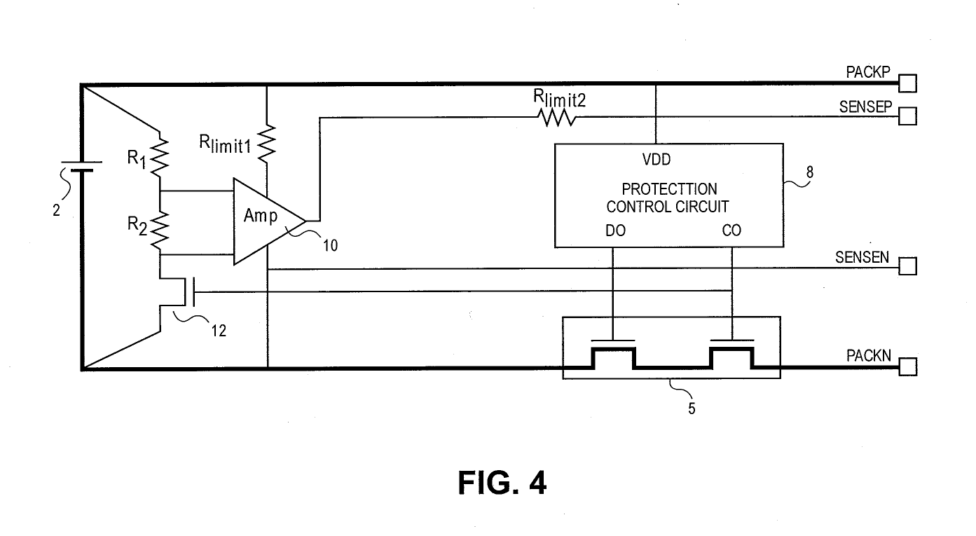

As seen in FIG. 1, the negative leg 4b of the sense path is directly connected to the electrochemical cell assembly 2 and, in particular, to the negative cell terminal, at a point upstream of where the sense switch circuit 6 is connected in the sense path, also noting that the negative sense terminal SENSEN is at a point downstream of the switch circuit 6. In other words, the sense switch circuit 6 is shown as being in between the negative cell terminal and the negative pack terminal. Here, it should also be noted that as an alternative to locating the sense switch circuit 6 in the negative leg of the sense path, it could be located in the positive leg of the sense path (or there could be two sense switch circuits one in each leg). It should be noted that in this embodiment, there are no active devices in the sense path, between the terminals of the cell assembly 2 and the sense terminals, except for active switching devices. This is in contrast to another embodiment of the invention described below in FIG. 4 in which the sense path contains an amplifier.

In one embodiment, the protection control circuit 8, the sense switch circuit 6, and the power switch circuit 5 are all packaged within a battery pack housing, and in particular one having a single cell. A single cell may be composed of multiple sub-cells connected in parallel (to increase charge capacity of the pack). In another embodiment, the battery pack housing may have multiple cells connected in series (to increase the pack voltage, which is the total voltage of the battery pack 1). In that case, the electromechanical cell assembly 2 in FIG. 1 represents multiple cells connected in series, and the sense terminals SENSEN, SENSEP are used to sense the total voltage of the series connected, multiple cells. The pack terminals and sense terminals may be individually accessible from outside the housing, e.g. as individual contacts or pins of a battery pack connector system in the pack housing.

Referring now to FIG. 2, the battery pack 1 may be part of a battery system that has an external voltage sensing circuit 14 that is connected to the SENSEP and SENSEN terminals as shown. The voltage sensing circuit 14 in FIG. 2 receives an analog signal input through the SENSEP and SENSEN terminals, and may perform analog signal conditioning, and/or conversion to digital format, while the voltage is monitored during battery charging. A battery charging circuit 3 delivers charging current to the pack terminals, PACKP and PACKN. The charging circuit 3 in that case will increase, reduce, and eventually cutoff the charging current in the power path of the battery pack, during a charging cycle, in accordance with the pack voltage as measured by the voltage sensing circuit 14 through the sense terminals. A cutoff voltage representing a fully charged state may be programmed or stored, in a charging voltage set point circuit 16, and a comparator 17 circuit compares voltage that is obtained through the sense terminals to the predetermined cutoff voltage, to decide when the battery pack has reached its fully charged state (at which point the comparator 17 may signal a power supply 18 to completely cut off the charging current in the power path). As explained above, sensing of the pack voltage through dedicated sense lines helps maintain accurate control at the end of the charging cycle of the cell assembly 2 so that the pack 1 becomes fully charged, regardless of the parasitic resistance drops that are inherent in the power path and that if relied upon will exacerbate the charging accuracy particularly at high charge current levels.

The battery charging circuit 3 of FIG. 2 may be used to illustrate the following method for charging a battery. A pack voltage of the battery is sensed through a pair of sense terminals, which are separate from a pair of pack terminals (also referred to as power terminals) of the battery. Analog signal conditioning and/or conversion to digital format may be performed on the sensed pack voltage. The sensed pack voltage is monitored during battery charging, while a charging current is delivered to the pack terminals. The charging current is increased, and then reduced, and then cutoff, during a charging cycle, in accordance with the sensed pack voltage. A predetermined cutoff voltage representing a fully charged state is compared to the sensed pack voltage, to decide when the battery pack has reached its fully charged state. The charging current is cut off in response to the comparison indicating a fully charged state is reached. As explained above, sensing of the pack voltage through dedicated sense lines helps maintain accurate control at the end of the charging cycle so that the battery becomes fully charged, regardless of the parasitic resistance drops that are inherent in the power path (that connects the pack terminals to the electrochemical cell assembly of the battery) and that if relied upon will exacerbate the charging accuracy particularly at high charge current levels (e.g., over 1C).

Turning now to FIG. 3, this figure illustrates variations to the battery system of FIG. 1 using several features, not all of which may be present within the same embodiment, and where some features may be omitted as explained below. First, the protection control circuit 8 has been replaced with a primary protection control circuit 8a and a secondary protection control circuit 8b each of which may have the same general functions as the protection circuit 8 but together serve as a redundant protection control circuit. In one embodiment, the primary protection control circuit 8a has a lower threshold voltage for an overcharge condition than the secondary protection control circuit 8b, such that if the primary were to fail then the secondary would act to signal its associated power switch circuit 5b into the open circuit state (in response to any detectable fault condition). In another embodiment, the threshold parameters used by the protection control circuits 8a, 8b may be the same.

FIG. 3 also shows how the redundant primary and secondary protection control circuits 8a, 8b may each be controlling their respective power switch circuits 5a, 5b, and their respective sense switch circuits 6a, 6b, to enhance the redundancy effect. Viewed another way, the power switch circuit 5 of FIG. 1 is now replaced with two series connected circuits 5a, 5b for redundancy while the sense switch circuit 6 has been replaced with two series connected circuits 6a, 6b. An output control signal of the protection control circuit 8a, 8b may still be shared (as shown), where each output control DO, CO may be connected to both a power switch circuit 5a, 5b and a sense switch circuit 6a, 6b.

Another feature that is depicted in FIG. 3 is the type of active device that is used as part of the switch circuits 5, 6. In this case, each switch circuit 5a, 5b, 6a, 6b has a pair of insulated gate field effect transistors that are connected in series and where each receives a separate control signal. The control signals DO and CO are normally asserted, and then are both de-asserted in response to the protection control circuit 8a, 8b having detected a fault condition. The de-assertion of DO and CO causes their respective connected field effect transistors to be turned off. Other redundant arrangements for the combination of the protection circuit 8 and the power and sense switch circuits 5, 6 are possible.

FIG. 3 also shows a similar variation to the sense switch circuit 6, which has been replaced with a primary switch circuit 6a and a secondary switch circuit 6b. Note how these switch circuits 6a, 6b may be controlled by the same control signals DO, CO that are used to control the power switch circuits 5a, 5b. This approach is not necessary, as it may be possible to add additional protection control circuitry that controls the sense path switch circuits 6a, 6b, separately from the power switch circuits 5a, 5b; however, the shared arrangement in FIG. 3 presents an especially efficient circuit design in that the existing or conventional protection control circuitry (here primary protection control circuits 8a, 8b) are being multi-purposed to protect the cell assembly 2 against faults on both the power path and the sense path.

FIG. 3 shows yet another variation of the protection scheme for protecting the cell assembly 2 against faults that may be rooted in the sense path, namely by the addition of a discrete resistor 7 in the positive leg of the sense path, and a discrete resistor 10 in series in the negative leg of the sense path. Each of the discrete resistors 7, 10 serves to limit current through the sense path, for example, during an accidental short circuit between the two legs, thereby helping prevent physical damage due to short circuit current induced overheating of the sense path. Note that as an alternative to having both discrete resistors 7, 10 in the sense path, it is possible to omit one of the resistors, thereby leaving just the resistor 7 in the positive leg or the resistor 10 in the negative leg. Providing the same value discrete resistors in both the positive and negative legs of the sense path, however, may help maintain a balanced voltage measurement.

Turning now to FIG. 4, this is a block diagram and circuit schematic of another embodiment of the battery system in which the separate sense path contains an amplifier 10 that drives the sense terminals, SENSEP and SENSEN, with a conditioned or sampled version of the voltage of the cell 2. In this embodiment, the sense path in effect has a voltage sensing circuit composed of first and second input nodes that are directly connected to the positive and negative cell terminals, respectively, of the cell assembly 2, while first and second output nodes are connected to the positive and negative sensed terminals, SENSEP and SENSEN, respectively. In this case, the voltage sensing circuit is composed of a voltage divider circuit that includes resistor ladder R₁, R₂ which are connected to the first and second input nodes through a transistor switch circuit 12 (depicted here as a single insulated gate field effect transistor, just as an example). An output of the voltage divider is connected to a pair of input nodes of an amplifier 10. The amplifier 10 may be powered by the cell assembly 2 as shown, through an optional current limiting resistor Rₗᵢₘᵢₜ₁ that is connected to the positive cell terminal through the positive leg of the power path (or alternatively, directly to the positive cell terminal through a separate path—not shown). An output of the amplifier 10 may also have current limiting resistor Rᵢᵢₘᵢₜ₂ which is connected to the SENSEP terminal, while a ground or power supply return terminal of the amplifier 10 is connected to the SENSEN terminal and also to the negative cell terminal, through the negative leg of the power path as shown (or alternatively directly through a separate path—not shown). When the transistor switch circuit 12 is in its open circuit state, there is essentially no current through the voltage divider such that the amplifier 10 has a zero voltage input and therefore a zero voltage output. When the transistor switch 12 is turned on or is in its short circuit state, where this occurs in response to a control signal being asserted only during charging, e.g. the CO signal produced by the protection circuit, the voltage sensing circuit is deemed activated. In that state, the amplifier input receives an expected voltage representing a measure of the voltage of the cell assembly 2, and amplifies this input voltage at its output, which is connected to the SENSEP and SENSEN terminals. This enables a charging circuit 3 (see FIG. 2) to rely upon the analog output of the voltage sensing circuit and achieve more accurate control of the full charge state of the cell assembly 2. It should be noted that while the control signal depicted in FIG. 4 that activates the voltage sensing circuit is produced by the protection control circuit 8 and may be limited to a signal that is asserted only during charging of the cell assembly, an alternative is to generate this control signal by a different circuit, e.g. one that detects a charging cycle taking place in an external charging circuit, that is outside of the pack.

Several variations described above for the embodiment of FIG. 1 are also applicable to the embodiment of FIG. 4, including, for example, the case where the battery system of FIG. 4 is a single cell battery pack, rather than a multi-cell pack where the cell assembly 2 is multiple cells that are connected in series. Also, the cell assembly 2, the power switch circuit 5, and the voltage sensing circuit as depicted in FIG. 4 may all be packaged within a battery pack housing. The pack terminals and the sense terminals may continue to be individually accessible from outside the housing in such an embodiment, for example as part of a battery pack connector system in which the pack terminals and sense terminals are individual contacts or pins of the connector system. In a further variation, the protection control circuit 8 is included within the pack housing, and is powered by the cell assembly 2 and is connected to signal the power switch circuit 5 as shown, through one or more control signals DO, CO. In such an embodiment, the protection control circuit 8 signals the switch circuit into an open circuit state in response to detecting a fault condition, which may be, for example, an overvoltage state or an undervoltage state. In some cases an overcurrent state may also be detected through a current sensing scheme. Note that in general, the protection control circuit 8 need not have the capability to detect all such faults, but rather may be designed to only detect a certain type of fault, e.g. overvoltage and undervoltage. In that case, there may be a separate circuit, such as a separate element as part of the power switch circuit 5 that detects an overcurrent condition and in response causes the power switch circuit 5 to go into its open circuit state, e.g. a resettable thermally sensitive overcurrent protector device.

Note also that the battery charging scheme shown in FIG. 2 may also be applied to the embodiment of FIG. 4, where in that case the voltage sensing circuitry 14, that is associated with the battery charging circuit 3 that is connected to the sense terminals SENSEN, SENSEP, may be simply an analog-to-digital converter, for example, that is able to convert the output voltage of the amplifier 10 into digital form. In that case, the charging circuit 3 continues with monitoring of the cell voltage in the digital domain, e.g. as part of a programmed processor or microcontroller on a main logic board or in a power management unit integrated circuit (e.g., outside of the pack housing). In such an embodiment, the charging circuit 3 of FIG. 2 can be viewed as having a pair of cell voltage sense inputs that are connected to the sense terminals, and a pair of power nodes that are connected to the pack terminals, respectively. The charging circuit 3 in that case increases, reduces and eventually cuts off current in the power path during a charging cycle of the cell assembly 2, in accordance with cell voltage that has been obtained through the sense terminals, for example after a conversion into digital format.

While certain embodiments have been described and shown in the accompanying drawings, it is to be understood that such embodiments are merely illustrative of and not restrictive on the broad invention, and that the invention is not limited to the specific constructions and arrangements shown and described, since various other modifications may occur to those of ordinary skill in the art. The description is thus to be regarded as illustrative instead of limiting.

What is claimed is:

1. A battery system comprising:
a positive pack terminal and a negative pack terminal;
a positive sense terminal and a negative sense terminal;
an electrochemical cell assembly having a positive cell terminal and a negative cell terminal;
an electrically conductive power path having a positive leg that connects the positive cell terminal to the positive pack terminal, and a negative leg that connects the negative cell terminal to the negative pack terminal;
a power switch circuit connected in the power path;
an electrically conductive sense path, separate from the power path, having a positive leg that connects the positive cell terminal to the positive sense terminal, and a negative leg that connects the negative cell terminal to the negative sense terminal; and
a sense switch circuit connected in the sense path.

2. The battery system of claim 1 wherein the electrochemical cell assembly is one of (i) a single cell having one or more sub-cells connected in parallel, or (ii) multiple cells connected in series.

3. The battery system of claim 1 wherein the sense switch circuit is connected between the positive cell terminal and the positive sense terminal.

4. The battery system of claim 1 wherein the sense switch circuit is connected between the negative cell terminal and the negative sense terminal.

5. The battery system of claim 1 further comprising a discrete resistor connected in series with the sense path.

6. The battery system of claim 1 wherein there are no active devices in the sense path, between the cell terminals and the sense terminals, except for one or more transistor based switches.

7. The battery system of claim 1 further comprising a protection control circuit that is powered by the cell assembly and connected to the power switch circuit, wherein the protection control circuit signals the power switch circuit into an open circuit state in response to detecting a fault condition.

8. The battery system of claim 7 wherein the fault condition is one of a) an overvoltage state, b) an undervoltage state, or c) an overcurrent state.

9. The battery system of claim 7 wherein the protection control circuit is connected to the sense switch circuit and signals the sense switch circuit into an open circuit state in response to detecting the fault condition.

10. The battery system of claim 9 wherein the same control signal from the protection control circuit is used to signal both the power switch circuit and the sense switch circuit into the open circuit state in response to detecting the fault condition.

11. The battery system of claim 1 wherein the sense switch circuit is connected in the negative leg of the sense path.

12. The battery system of claim 7 wherein the protection control circuit, the power switch circuit, and the sense switch circuit are all packaged within a battery pack housing, and the pack terminals and sense terminals are individually accessible from outside of the housing.

13. The battery system of claim 12 further comprising a pack connector system, wherein the pack terminals and sense terminals are individual contacts of the pack connector system.

14. The battery system of claim 1 further comprising:
a voltage sensing circuit connected to the sense terminals; and
a charging circuit connected to the pack terminals, wherein the charging circuit increases, reduces and cuts off current in the power path during a charging cycle of the cell in accordance with voltage as measured by the voltage sensing circuit through the sense terminals.

15. A battery system comprising:
a positive pack terminal and a negative pack terminal;
a positive sense terminal and a negative sense terminal;
an electrochemical cell assembly having a positive cell terminal and a negative cell terminal;
an electrically conductive power path that connects the positive and negative cell terminals to the positive and negative pack terminals, respectively;
a switch circuit connected in the power path; and
a voltage sensing circuit having first and second input nodes connected to the positive and negative cell terminals, respectively, and first and second output nodes connected to the positive and negative sense terminals, respectively.

16. The battery system of claim 15 wherein the cell assembly, the switch circuit, and the voltage sensing circuit are all packaged within a battery pack housing, and the pack terminals and sense terminals are individually accessible from outside the housing.

17. The battery system of claim 16 further comprising a pack connector system, wherein the pack terminals and sense terminals are individual contacts of the pack connector system.

18. The battery system of claim 15 wherein the voltage sensing circuit comprises a voltage divider circuit connected to the first and second input nodes, and an amplifier whose input is connected to an output of the voltage divider circuit, and wherein a control signal activates the voltage sensing circuit to sense voltage of the cell.

19. The battery system of claim 18 further comprising:
a protection control circuit that is powered by the cell assembly and is connected to the switch circuit, wherein the protection control circuit signals the switch circuit into an open circuit state in response to detecting a fault condition.

20. The battery system of claim 19 wherein the fault condition is one of a) an overvoltage state, b) an undervoltage state, or c) an overcurrent state.

21. The battery system of claim 19 wherein the control signal that activates the voltage sensing circuit is produced by the protection control circuit.

22. The battery system of claim 15 further comprising:
a charging circuit having a pair of voltage sense inputs connected to the sense terminals, and a pair of power nodes connected to the pack terminals, respectively, wherein the charging circuit increases, reduces and cuts off current in the power path during a charging cycle of the cell assembly in accordance with voltage obtained through the sense terminals.

23. A battery system comprising:
a single cell battery pack having,
a positive pack terminal and a negative pack terminal;
a positive sense terminal and a negative sense terminal;
an electrochemical cell having a positive cell terminal and a negative cell terminal;
an electrically conductive power path having a positive leg that connects the positive cell terminal to the positive pack terminal, and a negative leg that connects the negative cell terminal to the negative pack terminal; and
an electrically conductive sense path, separate from the power path, having a positive leg that connects the positive cell terminal to the positive sense terminal, and a negative leg that connects the negative cell terminal to the negative sense terminal.

24. The battery system of claim 23 further comprising:
a power switch circuit connected in the power path; and
a sense switch circuit connected in the sense path.

25. A method for charging a battery, comprising:
sensing pack voltage of a battery through a pair of sense terminals, which are separate from a pair of power terminals of the battery;
monitoring the sensed pack voltage during battery charging, while a charging current is delivered to the power terminals, by comparing the sensed pack voltage to a predetermined cutoff voltage representing a fully charged state for the battery; and
cutting off the charging current in response to the comparison indicating that a fully charged state is reached.

26. The method of claim 25 further comprising performing analog signal conditioning or conversion to digital format or both, upon the sensed pack voltage.
